(19) United States
(12) Patent Application Publication
(10) Pub. No.: US 2026/0231615 A1
(43) Pub. Date: Aug. 6, 2026

(54) DISPLAY PANEL AND MANUFACTURING METHOD THEREFOR, AND DISPLAY DEVICE

(71) Applicant: BOE Technology Group Co., Ltd., Beijing (CN)

(72) Inventors: Yue ZHANG, Beijing (CN); Hongli WANG, Beijing (CN)

(73) Assignee: BOE Technology Group Co., Ltd., Beijing (CN)

(21) Appl. No.: 18/865,470

(22) PCT Filed: Jul. 26, 2023
(86) PCT No.: PCT/CN2023/109280

§ 371 Date: Nov. 13, 2024

(30) Foreign Application Priority Data
Jul. 28, 2022 (CN) 202210901592.9

(51) Int. Cl. H10K 59/122

(52) U.S. Cl. CPC H10K 59/122

(57) ABSTRACT

Provided are a display panel and a manufacturing method therefor, and a display device. The display panel includes: an array substrate; and a first defining layer, which includes a first delimiting portion and a second delimiting portion, wherein both the first delimiting portion and the second delimiting portion extend in a first direction, the second delimiting portion is located on a side of the first delimiting portion in a second direction, each of the first delimiting portion and the second delimiting portion has a bottom end close to the array substrate and a top end away from the array substrate, and the distance between the bottom end and the top end of the first delimiting portion is less than the distance between the bottom end and the top end of the second delimiting portion.

### CROSS-REFERENCE TO RELATED APPLICATIONS

The present application is a U.S. National Stage Application of International Application No. PCT/CN2023/109280, filed on Jul. 26, 2023, which is based upon and claims the priority to the Chinese Patent Application NO. 202210901592.9, entitled “DISPLAY PANEL AND MANUFACTURING METHOD THEREFOR, AND DISPLAY DEVICE”, filed on Jul. 28, 2022, the entire contents of each are hereby incorporated by reference.

### TECHNICAL FIELD

The present disclosure relates to the field of display technologies, and in particular to a display panel and a manufacturing method thereof, and a display device.

### BACKGROUND

In inkjet-printed Organic Light Emitting Diode (OLED) display panels, the printed ink usually moves along Pixel Definition Layers (PDLs) within sub-pixel areas, causing the ink to form an uneven film in different positions of sub-pixels, affecting the device life and display effect.

In the prior art, the uniformity of film formation in the sub-pixel area is improved by enabling the printed ink in a row of sub-pixel areas to be in communication.

It should be noted that the information disclosed in the Background section above is only for enhancing the understanding of the background of the present disclosure, and thus may include information that does not constitute prior art known to those of ordinary skill in the art.

### SUMMARY

According to a first aspect of the present disclosure, there is provided a display panel, including:
an array substrate; and
a first definition layer, disposed on a side of the array substrate, and including a first definition portion and a second definition portion, wherein the first definition portion and the second definition portion are extended along a first direction, the second definition portion is located on a side of the first definition portion along a second direction, the first definition portion and the second definition portion are both provided with a bottom end close to the array substrate and a top end away from the array substrate, and a distance between the bottom end and the top end of the first definition portion is smaller than a distance between the bottom end and the top end of the second definition portion.

In an embodiment of the present disclosure, liquid repellency of the first definition portion is smaller than liquid repellency of the second definition portion.

In an embodiment of the present disclosure, ends of the first definition portion and the second definition portion close to the array substrate have liquid affinity;
ends of the first definition portion and the second definition portion away from the array substrate have liquid repellency; and
the liquid repellency of the end of the first definition portion away from the array substrate is smaller than the liquid repellency of the end of the second definition portion away from the array substrate.

In an embodiment of the present disclosure, the first definition layer further includes:
a plurality of third definition portions, extended along the first direction, wherein the plurality of third definition portions are arranged at intervals along the second direction on a side of the second definition portion away from the first definition portion;
a third definition portion is provided with a bottom end close to the array substrate and a top end away from the array substrate, and a distance between the bottom end and the top end of the third definition portion is greater than the distance between the bottom end and the top end of the second definition portion; and
distances between bottom ends and top ends of the plurality of third definition portions increase sequentially in a direction from the first definition portion to the second definition portion.

In an embodiment of the present disclosure, the display panel further includes:
a planarization layer, disposed between the array substrate and the first definition layer, wherein the planarization layer is provided with a first groove and a second groove, and a depth of the second groove is greater than a depth of the first groove;
wherein an orthographic projection of the first groove on the array substrate is located within an orthographic projection of the first definition portion on the array substrate, and an orthographic projection of the second groove on the array substrate is located within an orthographic projection of the second definition portion on the array substrate; and
at least part of the first definition portion is filled in the first groove, and at least part of the second definition portion is filled in the second groove.

In an embodiment of the present disclosure, the first definition layer further includes a plurality of third definition portions;
the planarization layer is further provided with a plurality of third grooves, a depth of a third groove is greater than the depth of the second groove, and the third grooves are arranged in a one-to-one correspondence with the third definition portions in a direction perpendicular to the array substrate;
an orthographic projection of the third grooves on the array substrate is located within an orthographic projection of the third definition portions on the array substrate, and at least part of the third definition portions is filled in the third grooves; and
depths of the plurality of third grooves increase sequentially in a direction from the first groove to the second groove.

In an embodiment of the present disclosure, the depths of the first groove, the second groove and the third groove are 0.2-0.7 μm.

In an embodiment of the present disclosure, the distance between the bottom end and the top end of the first definition portion, the distance between the bottom end and the top end of the second definition portion, and the distances between the bottom ends and the top ends of the third definition portions are all 0.3-0.8 μm.

In an embodiment of the present disclosure, the display panel further includes:
a planarization layer, disposed between the array substrate and the first definition layer; and
a distance between the top end of the first definition portion and a surface of the planarization layer away from the array substrate is smaller than a distance between the top end of the second definition portion and the surface of the planarization layer away from the array substrate.

In an embodiment of the present disclosure, the first definition layer further includes a plurality of third definition portions, and a distance between a top end of a third definition portion and the surface of the planarization layer away from the array substrate is greater than the distance between the top end of the second definition portion and the surface of the planarization layer away from the array substrate; and
distances between the top ends of the plurality of third definition portions and the surface of the planarization layer away from the array substrate increase sequentially in a direction from the first definition portion to the second definition portion.

In an embodiment of the present disclosure, materials of the first definition portion and the second definition portion include liquid-affinitive materials, and the distance between the top end of the first definition portion and the surface of the planarization layer away from the array substrate and the distance between the top end of the second definition portion and the surface of the planarization layer away from the array substrate are 0.3-1 μm.

In an embodiment of the present disclosure, materials of the first definition portion and the second definition portion include liquid-repellent materials, and the distance between the top end of the first definition portion and the surface of the planarization layer away from the array substrate and the distance between the top end of the second definition portion and the surface of the planarization layer away from the array substrate are 0.3-0.5 μm.

In an embodiment of the present disclosure, the first definition portion includes:
a first bottom definition layer, disposed on a side of the array substrate; and
a first top definition layer, disposed on a side of the first bottom definition layer away from the array substrate, wherein the first top definition layer includes at least two first definition dams extended along the first direction, and the at least two first definition dams are arranged at intervals along the second direction;
the second definition portion includes:
a second bottom definition layer, disposed on a side of the array substrate; and
a second top definition layer, disposed on a side of the second bottom definition layer away from the array substrate, wherein the second top definition layer includes at least two second definition dams extended along the first direction, and the at least two second definition dams are arranged at intervals along the second direction;
wherein each of the first definition dams has a bottom end close to the first bottom definition layer and a top end away from the first bottom definition layer, and each of the second definition dams has a bottom end close to the second bottom definition layer and a top end away from the second bottom definition layer; and
a maximum distance between the bottom end and the top end of the first definition dam is smaller than a maximum distance between the bottom end and the top end of the second definition dam.

In an embodiment of the present disclosure, the display panel further includes a plurality of third definition portions;
a third definition portion includes:
a third bottom definition layer, disposed on a side of the array substrate;
a third top definition layer, disposed on a side of the third bottom definition layer away from the array substrate, wherein the third top definition layer includes at least two third definition dams extended along the first direction, and the at least two third definition dams are arranged at intervals along the second direction;
each of the third definition dams has a bottom end close to the third bottom definition layer and a top end away from the third bottom definition layer;
a maximum distance between the bottom end and the top end of the third definition dam is greater than the maximum distance between the bottom end and the top end of the second definition dam.

In an embodiment of the present disclosure, thicknesses of the first bottom definition layer and the second bottom definition layer are both 0.2-0.3 μm.

In an embodiment of the present disclosure, materials of the first definition portion and the second definition portion include liquid-affinitive materials, and the distance between the bottom end and the top end of the first definition dam and the distance between the bottom end and the top end of the second definition dam are both 0.3-0.7 μm.

In an embodiment of the present disclosure, materials of the first definition portion and the second definition portion include liquid-repellent materials, and the distance between the bottom end and the top end of the first definition dam and the distance between the bottom end and the top end of the second definition dam are both 0.3-0.5 μm.

In an embodiment of the present disclosure, the display panel further includes:
a second definition layer, including a plurality of fourth definition portions extended along the second direction and arranged at intervals along the first direction, wherein a plurality of sub-pixel areas are defined by the first definition layer and the second definition layer; and
a hole injection layer, located in each of the sub-pixel areas, wherein hole injection layers corresponding to sub-pixel areas located on both sides of the first definition portion along the second direction or hole injection layers corresponding to sub-pixel areas located on both sides of the second definition portion along the second direction are in communication.

In an embodiment of the present disclosure, the first definition layer further includes:
a plurality of fifth definition portions, extended along the first direction and arranged at intervals along the second direction;
the first direction is a row direction, and the second direction is a column direction;
an area defined between two adjacent fifth definition portions is a communication area, and the communication area includes at least one first definition portion and at least one second definition portion; and
hole injection layers of a plurality of the sub-pixel areas in the same column in each communication area are in communication, and hole injection layers of sub-pixel areas in two adjacent communication areas are not in communication.

According to a second aspect of the present disclosure, there is provided a method for manufacturing a display panel, including:
providing an array substrate; and
forming a first definition layer on a side of the array substrate, wherein the first definition layer includes a first definition portion and a second definition portion, the first definition portion and the second definition portion are extended along a first direction, the second definition portion is located on a side of the first definition portion along a second direction, the first definition portion and the second definition portion are both provided with a bottom end close to the array substrate and a top end away from the array substrate, and a distance between the bottom end and the top end of the first definition portion is smaller than a distance between the bottom end and the top end of the second definition portion.

In an embodiment of the present disclosure, the method further includes:
forming a second definition layer on a side of the first definition layer away from the array substrate, wherein the second definition layer includes a plurality of fourth definition portions extended along the second direction and arranged at intervals along the first direction, and a plurality of sub-pixel areas are defined by the first definition layer and the second definition layer; and
adding a hole injection material solution into a sub-pixel, wherein hole injection layers corresponding to sub-pixel areas located on both sides of the first definition portion along the second direction or hole injection layers corresponding to sub-pixel areas located on both sides of the second definition portion along the second direction are in communication.

### BRIEF DESCRIPTION OF THE DRAWINGS

The above and other features and advantages of the present disclosure will become more apparent by describing example embodiments thereof in detail with reference to the drawings.

FIG. 1 is a schematic planar structural diagram of a part of a display panel in an embodiment of the present disclosure;

FIG. 2 is a schematic cross-sectional view of a A-A plane in FIG. 1;

FIG. 3 is a schematic diagram of a structure after a first electrode layer is formed in an embodiment of the present disclosure;

FIG. 4 is a schematic diagram of a structure after a first liquid-repellent material layer is formed in an embodiment of the present disclosure;

FIG. 5 is a schematic diagram of a structure after a first definition layer is formed in an embodiment of the present disclosure;

FIG. 6 is another schematic cross-sectional view of a A-A plane of FIG. 1;

FIG. 7 is a schematic diagram of a structure after a first electrode layer is formed in another embodiment of the present disclosure;

FIG. 8 is a schematic diagram of a structure after a first material layer is formed in another embodiment of the present disclosure;

FIG. 9 is a schematic diagram of a structure after a first definition layer is formed in another embodiment of the present disclosure;

FIG. 10 is a schematic planar structural diagram of a part of a display panel in another embodiment of the present disclosure;

FIG. 11 is a schematic cross-sectional view of a B-B plane in FIG. 10;

FIG. 12 is a schematic diagram of a structure after a liquid-affinitive material layer is formed in an embodiment of the present disclosure;

FIG. 13 is a schematic diagram of a structure after each bottom definition layer is formed in an embodiment of the present disclosure;

FIG. 14 is a schematic diagram of a structure after a buffer material layer is formed in an embodiment of the present disclosure;

FIG. 15 is a schematic diagram of a structure after each definition dam is formed in an embodiment of the present disclosure;

FIG. 16 is a schematic diagram of a structure after each definition dam is formed in another embodiment of the present disclosure;

FIG. 17 is a schematic diagram of a structure after each definition dam is formed in yet another embodiment of the present disclosure; and

FIG. 18 is a schematic planar structural diagram of a display panel in an embodiment of the present disclosure.

Reference signs of main elements in the figures are described as follows:
01—array substrate; 1—substrate; 2—driving circuit layer; 21—active layer; 22—first gate insulation layer; 23—first gate metal layer; 24—second gate insulation layer; 25—interlayer dielectric layer; 26—source-drain metal layer; 27—planarization layer; 271—first groove; 272—second groove; 273—third groove; 3—first definition layer; 31—first definition portion; 311—first bottom definition layer; 312—first top definition layer; 3121—first definition dam; 32—second definition portion; 321—second bottom definition layer; 322—second top definition layer; 3221—second definition dam; 33—third definition portion; 331—third bottom definition layer; 332—third top definition layer; 3321—third definition dam; 34—fifth definition portion; 4—second definition layer; 41—fourth definition portion; 02—communicaiton area; 30—sub-pixel area; 51—first electrode layer; 52—hole injection layer; 031—first liquid-repellent material layer; 032—first material layer; 033—liquid-affinitive material layer; 034—buffer material layer; X—first direction; Y—second direction.

### DETAILED DESCRIPTION

Example embodiments will now be described more fully with reference to the accompanying drawings. However, the example embodiments can be implemented in a variety of forms and should not be construed as being limited to examples set forth herein; rather, these embodiments are provided so that the present disclosure will be more complete and comprehensive so as to convey the idea of the example embodiments to those skilled in this art. The described features, structures or characteristics may be combined in any suitable manner in one or more embodiments. In the following description, many specific details are provided to give a full understanding of the embodiments of the present disclosure.

In the figures, thicknesses of areas and layers may be exaggerated for clarity. The same reference numerals in the drawings denote the same or similar structures, and thus their detailed description will be omitted

The features, structures, or characteristics described may be combined in any suitable manner in one or more embodiments. In the following description, many specific details are provided to give a full understanding of the embodiments of the present disclosure. However, those skilled in the art will appreciate that the technical solution of the present disclosure may be practiced without one or more of the specific details, or other methods, components, materials, and the like may be employed. In other instances, well-known structures, materials or operations are not shown or described in detail to avoid obscuring the main technical ideas of the present disclosure.

When a structure is “on” another structure, it may mean that the structure is integrally formed on the other structure, or that the structure is “directly” disposed on the other structure, or that the structure is “indirectly” disposed on the other structure through another structure.

The terms “a”, “an” and “the” are used to indicate that there are one or more elements/components or the like; the terms “include” and “have” are used to indicate an open meaning of including and means that there may be additional elements/components/etc. in addition to the listed elements/components/etc. The terms “first”, “second”, etc. are used only as markers, and do not limit the number of objects.

Film-forming methods of OLED mainly include an evaporation process or a solution process. The evaporation process is more mature in small-size applications, and this technology has been applied to mass production at present. The film-forming methods of solution process mainly include inkjet printing, nozzle coating, spin coating, screen printing, etc. Inkjet printing technologies are considered to be an important way to achieve mass production of large-size OLEDs due to its high material utilization rate and ability to achieve large sizes.

In inkjet-printed OLEDs, the printed ink usually moves along Pixel Definition Layers (PDLs) within sub-pixel areas, causing the ink to form an uneven film in different positions of sub-pixels, affecting the device life and display effect.

In the related arts, line bank technologies are used to improve the above problems. That is, a column of sub-pixels of the same color is made to be in communication for unified printing. The pixel definition layer in the line bank technologies includes a first pixel definition layer and a second pixel definition layer, the first pixel definition layer is made of a liquid-affinitive material, and the second pixel definition layer is made of a liquid-repellent material. A thickness of the first pixel definition layer is relatively low to ensure that sub-pixels of the same color in the same column can be in communication. However, in actual applications, since a printer table usually has a certain tilt angle, the ink in the sub-pixel areas of the same column will be gathered to one end due to gravity, affecting the display effect.

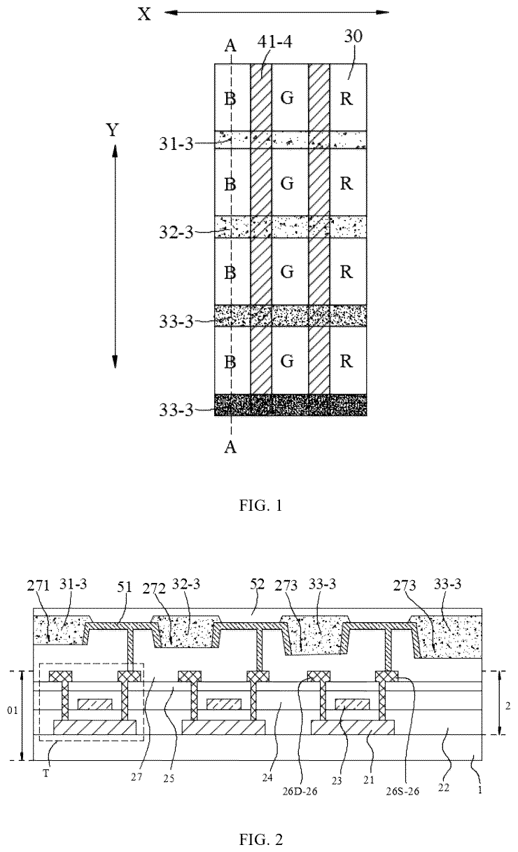

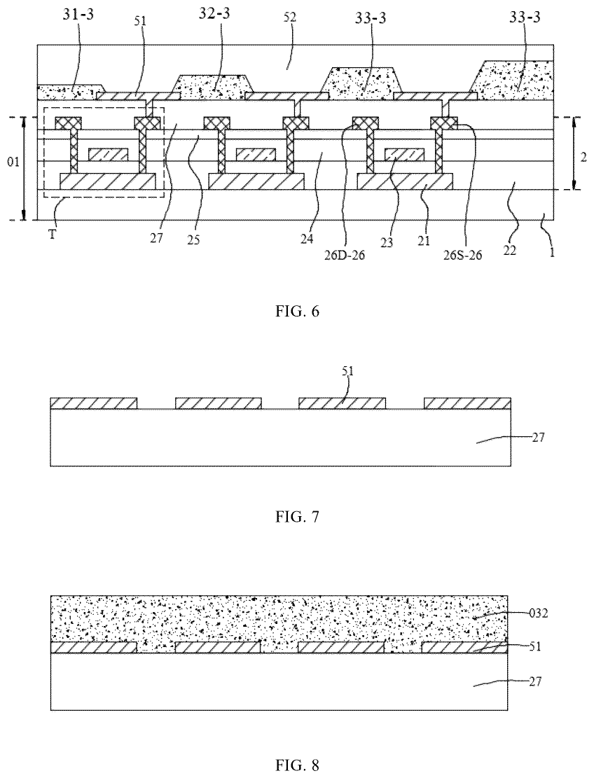

As shown in FIG. 1, FIG. 2, FIG. 6, FIG. 10 and FIG. 11, the present disclosure provides a display panel, including an array substrate 01 and a first definition layer 3. The first definition layer 3 is disposed on a side of the array substrate 01, and includes a first definition portion 31 and a second definition portion 32. The first definition portion 31 and the second definition portion 32 both extend along a first direction X, and the second definition portion 32 is located on a side of the first definition portion 31 along a second direction Y. The first definition portion 31 and the second definition portion 32 both have a bottom end close to the array substrate 01 and a top end away from the array substrate 01, and a distance between the bottom end and the top end of the first definition portion 31 is smaller than a distance between the bottom end and the top end of the second definition portion 32.

In the display panel provided by the present disclosure, the first definition layer 3 includes the first definition portion 31 and the second definition portion 32, both of which extend along the first direction X. The second definition portion 32 is located on a side of the first definition portion 31 along the second direction Y, and both of the first definition portion 31 and the second definition portion 32 have the bottom end close to the array substrate 01 and the top end away from the array substrate 01. The distance between the bottom end and the top end of the first definition portion 31 is smaller than the distance between the bottom end and the top end of the second definition portion 32. That is, heights of the first definition portion 31 and the second definition portion 32 are different, and this structural design helps to adjust flow velocitys of the ink at different positions of the first definition layer 3 during inkjet printing, and avoid the phenomenon of ink gathering at a certain position.

Various components of the display panel provided in embodiments of the present disclosure are described in detail below with reference to the accompanying drawings.

As shown in FIG. 1, FIG. 2, FIG. 6, FIG. 10 and FIG. 11, embodiments of the present disclosure provide a display panel, which may be an Organic Light-Emitting Diode (OLED) display panel. The display panel includes an array substrate 01 and a first definition layer 3.

In some embodiments, the array substrate includes a base substrate 1 and a driving circuit layer 2 disposed on a side of the base substrate 1. The base substrate 1 may be a base substrate of an inorganic material, or may be a base substrate of an organic material. For example, in an embodiment of the present disclosure, a material of the base substrate 1 may be a glass material such as soda-lime glass, quartz glass, sapphire glass, or may be a metal material such as stainless steel, aluminum, nickel, etc. The base substrate 1 may also be a flexible base substrate 1. For example, in an embodiment of the present disclosure, the material of the base substrate 1 may be polyimide (PI). The base substrate 1 may also be a composite of multiple layers of materials. For example, in an embodiment of the present disclosure, the base substrate 1 may include a bottom film, a pressure-sensitive adhesive layer, a first polyimide layer, and a second polyimide layer stacked in sequence.

The driving circuit layer 2 includes a pixel circuit, which is used to drive a light-emitting device of the OLED display panel to emit light. The pixel circuit may be a pixel circuit such as 7T1C, 7T2C, 6T1C or 6T2C, and its structure is not specifically limited here. nTmC means that a pixel circuit includes n transistors (represented by the letter “T”) and m capacitors (represented by the letter “C”).

In some embodiments of the present disclosure, the driving circuit layer 2 may be composed of a multi-layer film structure. Taking the transistor in the driving circuit as a top-gate thin film transistor as an example, the driving circuit layer 2 includes an active layer 21, a first gate insulation layer 22, a first gate metal layer 23, a second gate insulation layer 24, an interlayer dielectric layer 25 and a source-drain metal layer 26.

The active layer 21 is disposed on a side of the base substrate 1; the first gate insulation layer 22 is disposed on a side of the active layer 21 away from the base substrate 1, and the first gate insulation layer 22 covers the active layer 21; the first gate metal layer 23 is disposed on a side of the first gate insulation layer 22 away from the base substrate 1, and the first gate metal layer 23 may include the gate of the transistor T. The second gate insulation layer 24 is disposed on a side of the first gate metal layer 23 away from the base substrate 1, and the second gate insulation layer 24 covers the first gate metal layer 23; the interlayer dielectric layer 25 is disposed on a side of the second gate insulation layer 24 away from the base substrate 1; the source-drain metal layer 26 is disposed on a side of the interlayer dielectric layer 25 away from the base substrate 1, and the source-drain metal layer 26 includes a source 26S and a drain 26D of the transistor, and the source 26S and the drain 26D are coupled to the active layer 21.

The first definition layer 3 is disposed on a side of the base substrate 1, and includes a first definition portion 31 and a second definition portion 32, both of which extend along the first direction X, and the second definition portion 32 is located on a side of the first definition portion 31 along the second direction Y. In the present disclosure, the first direction X and the second direction Y have a certain angle, a range of which may be 0-90°. In an embodiment, the first direction X may be a row direction, and the second direction Y may be a column direction, which is not specifically limited in the present disclosure.

The first definition portion 31 and the second definition portion 32 both have a bottom end close to the array substrate 01 and a top end away from the array substrate 01, and a distance between the bottom end and the top end of the first definition portion 31 is smaller than a distance between the bottom end and the top end of the second definition portion 32. It should be noted that in the present disclosure, the bottom end of each definition portion close to the array substrate 01 refers to an end of the definition portion closest to the array substrate 01, that is, the lowest end, and the top end refers to an end of the definition portion farthest from the array substrate 01, that is, the highest end.

In some embodiments, the first definition layer 3 further includes a plurality of third definition portions 33 extending along the first direction X, and the plurality of third definition portions 33 are arranged at intervals along the second direction Y on a side of the second definition portion 32 away from the first definition portion 31. The third definition portion 33 has a bottom end close to the array substrate 01 and a top end away from the array substrate 01, and a distance between the bottom end and the top end of the third definition portion 33 is greater than the distance between the bottom end and the top end of the second definition portion 32. Distances between the bottom ends and the top ends of the plurality of third definition portions 33 increase in sequence in a direction from the first definition portion 31 to the second definition portion 32. In the embodiment, heights of respective definition portions in the first definition layer 3 increase or decrease in sequence, so that the problem of ink gathering at one end due to the tilt of the printer table can be improved. Specifically, height differences between respective definition portions (the first definition portion 31, the second definition portion 32 and the third definition portion 33) can be set according to the actual tilt of the printer table.

In some embodiments, the display panel further includes a second definition layer 4 disposed on a side of the first definition layer 3 away from the array substrate 01, and the second definition layer 4 includes a plurality of fourth definition portions 41, which extend along the second direction Y and are arranged at intervals along the first direction X. A plurality of sub-pixel areas 30 are defined by the first definition layer 3 and the second definition layer 4. Similarly, the fourth definition portion 41 has a bottom end close to the array substrate 01 and a top end away from the array substrate 01, and a distance between the bottom end and the top end of the fourth definition portion 41 is greater than the distance between the bottom end and the top end of each definition portion in the first definition layer 3. That is, in a direction perpendicular to the base substrate 1, a height of the second definition layer 4 is higher than a height of the first definition layer 3.

In some embodiments of the present disclosure, the display panel further includes a planarization layer 27 and a first electrode layer 51. The planarization layer 27 is disposed between the array substrate 01 and the first definition layer 3. Specifically, the planarization layer 27 is disposed between the source-drain metal layer 26 and the first definition layer 3. The first electrode layer 51 is disposed between the planarization layer 27 and the first definition layer 3, and the first electrode layer 51 includes a plurality of first electrodes. In the direction perpendicular to the base substrate 1, the sub-pixel areas 30 correspond to the first electrodes one-to-one, and an orthographic projection of a sub-pixel area 30 on the base substrate 1 is located within an orthographic projection of a first electrode on the base substrate 1. The plurality of sub-pixel areas 30 expose respective first electrodes one-to-one. The first electrode can be used as an anode of a light-emitting device. A shape of the first electrode can be set according to shape requirements of the sub-pixel, for example, an orthographic projection of the first electrode on the base substrate 1 is a rectangle, a regular polygon or other irregular closed figures.

In some embodiments of the present disclosure, the display panel further includes a hole injection layer 52 located in each sub-pixel area 30. Hole injection layers 52 corresponding to sub-pixel areas 30 located on both sides of the first definition portion 31 along the second direction Y or hole injection layers 52 corresponding to sub-pixel areas 30 located on both sides of the second definition portion 32 along the second direction Y are in communication.

Furthermore, the display panel further includes a hole transport layer, a light-emitting functional layer, an electron transport layer, an electron injection layer and a cathode, etc., which are sequentially arranged in a direction away from the array substrate 01 to form the light-emitting device. Each sub-pixel area defines a range of one light-emitting device, and each pixel circuit drives one light-emitting device to emit light.

In the present disclosure, the first direction X is the row direction, the second direction Y is the column direction, and the hole injection layers 52 of the sub-pixel areas 30 in the same column may be fully in communication or partially in communication. For example, in the same column of sub-pixel areas 30, hole injection layers 52 of every m sub-pixel areas 30 are in communication, and m may be any integer greater than 1. For example, hole injection layers 52 of every ten sub-pixel areas 30 may be in communication.

In the present disclosure, the specific structure of each definition portion in the first definition layer 3 may be various. The specific structure of the first definition layer 3 will be described in detail below in conjunction with specific embodiments.

As shown in FIGS. 1 and 2, in some embodiments, the planarization layer 27 is provided with a first groove 271 and a second groove 272, and a depth of the second groove 272 is greater than a depth of the first groove 271. An orthographic projection of the first groove 271 on the array substrate 01 is located within an orthographic projection of the first definition portion 31 on the array substrate 01, and an orthographic projection of the second groove 272 on the array substrate 01 is located within an orthographic projection of the second definition portion 32 on the array substrate 01. At least part of the first definition portion 31 is filled in the first groove 271, and at least part of the second definition portion 32 is filled in the second groove 272.

The first groove 271 and the second groove 272 may be elongated grooves extending along the first direction X, and the second groove 272 is located on a side of the first groove 271 along the second direction Y. Specifically, the shapes and positions of the first groove 271 and the second groove 272 may be set according to the shapes and positions of the first definition portion 31 and the second definition portion 32. In actual applications, a depth difference between the first groove 271 and the second groove 272 may be set according to the tilt angle of the printer table. The depth difference between the first groove 271 and the second groove 272 may vary, depending on different positions of the display panel. For example, the depth difference between the first groove 271 and the second groove 272 is 0-0.5 μm.

When the first definition layer 3 further includes the plurality of third definition portions 33, a plurality of third grooves 273 are further opened in the planarization layer 27. A depth of the third groove 273 is greater than the depth of the second groove 272. In the direction perpendicular to the array substrate 01, the third grooves 273 and the third definition portions 33 are arranged in a one-to-one correspondence. An orthographic projection of the third groove 273 on the array substrate 01 is located within an orthographic projection of the third definition portion 33 on the array substrate 01, and at least part of the third definition portion 33 is filled in the third groove 273. Depths of the plurality of third grooves 273 increase in sequence in the direction from the first groove 271 to the second groove 272

The depths of the first groove 271, the second groove 272 and the third groove 273 may be 0.2-0.7 μm. The depth of each groove in the planarization layer 27 may be any value within this range, as long as the above-mentioned depth variation relationship is satisfied. Depth differences between respective grooves may be set according to the inclination of the printer table and the number of grooves. For example, the depth differences between the respective grooves are 0-0.5um, which may be specifically 0.01 μm, 0.05 μm, 0.1 μm, 0.2 μm, 0.3 μm, 0.4 μm, 0.5 μm, etc.

In the embodiment, the distance between the bottom end and the top end of the first definition portion 31, the distance between the bottom end and the top end of the second definition portion 32, and the distance between the bottom end and the top end of the third definition portion 33 are all 0.3-0.8 μm, such as 0.3 μm, 0.4 μm, 0.5 μm, 0.6 μm, 0.7 μm, 0.8 μm, etc. Further, distances between the top end of the first definition portion 31, the top end of the second definition portion 32, and the top end of the third definition portion 33 and a surface of the planarization layer 27 away from the array substrate 01 are substantially equal.

In the embodiment, each of the first definition portion 31, the second definition portion 32 and the third definition portion 33 can be divided into two portions, one of which is a filling portion filled in their respective grooves, and the other is a protruding portion protruding from the surface of the planarization layer 27 away from the array substrate 01. A height of the protruding portion of each of the first definition portion 31, the second definition portion 32 and the third definition portion 33 is 0.1-0.8 μm.

Further, in the embodiment, the liquid repellency of the first definition portion 31 is less than that of the second definition portion 32, and when the first definition layer 3 further includes the plurality of third definition portions 33, the liquid repellency of the plurality of third definition portions 33 increases in sequence in the direction from the first definition portion 31 to the second definition portion 32. In the embodiment, as the liquid repellency increases, the flow velocity of the ink gradually slows down, thereby helping to improve the problem of ink gathering at one end.

The ends of the first definition portion 31 and the second definition portion 32 close to the array substrate 01 have the liquid affinity, the ends of the first definition portion 31 and the second definition portion 32 away from the array substrate 01 have the liquid repellency, and the liquid repellency of the end of the first definition portion 31 away from the array substrate 01 is less than the liquid repellency of the end of the second definition portion 32 away from the array substrate 01. Setting each definition portion to have a structure in which the bottom end is liquid affinitive, and the top end is liquid repellent, on the one hand, helps the ink of two adjacent sub-pixel areas 30 to be in communication, that is, the hole injection layers 52 corresponding to the sub-pixel areas 30 located on both sides of the first definition portion 31 or the sub-pixel areas 30 located on both sides of the second definition portion 32 are in communication, and on the other hand, can adjust the flow velocity of the ink to solve the technical problem of ink gathering at one end.

The materials of the first definition portion 31 and the second definition portion 32 may be doped liquid-repellent materials, and when the doped liquid-repellent material is baked, a liquid repellent component in this material will move to the surface, such as moving away from the array substrate 01. Thus, each definition portion with a liquid affinitive bottom end and a liquid repellent top end is formed. The doped material may include a fluorine-containing polymer, such as a copolymer of methyl methacrylate (MMA) and dodecafluoroheptyl methacrylate (also known as poly (methyl methacrylate-dodecafluoroheptyl methacrylate)), and may also include liquid affinitive magnetic nanoparticles, etc.

As shown in FIG. 1 and FIG. 6, in some other embodiments of the present disclosure, a distance between the top end of the first definition portion 31 and the surface of the planarization layer 27 away from the array substrate 01 is smaller than a distance between the top end of the second definition portion 32 and the surface of the planarization layer 27 away from the array substrate 01. A specific distance difference between these two distances can be set according to the tilt angle of the printer table and the position of each definition portion. For example, the distance difference between these two distances may be 0.2-1 μm. The distance between the top end of the first definition portion 31 and the surface of the planarization layer 27 away from the array substrate 01 and the distance between the top end of the second definition portion 32 and the surface of the planarization layer 27 away from the array substrate 01 are 0.3-1 μm, which may be specifically 0.3 μm, 0.4 μm, 0.5 μm, 0.6 μm, 0.7 μm, 0.8 μm, 0.9 μm, 1 μm.

In the present disclosure, the heights of the first definition portion 31 and the second definition portion 32 can be slightly adjusted according to their own different materials. For example, the materials of the first definition portion 31 and the second definition portion 32 include the liquid-affinitive material, and the distance between the top end of the first definition portion 31 and the surface of the planarization layer 27 away from the array substrate 01 and the distance between the top end of the second definition portion 32 and the surface of the planarization layer 27 away from the array substrate 01 are 0.3-1 μm. For another example, the materials of the first definition portion 31 and the second definition portion 32 include the liquid-repellent material, and the distance between the top end of the first definition portion 31 and the surface of the planarization layer 27 away from the array substrate 01 and the distance between the top end of the second definition portion 32 and the surface of the planarization layer 27 away from the array substrate 01 are 0.3-0.5 μm.

When the first definition layer 3 further includes the plurality of third definition portions 33, the distance between the top end of the third definition portion 33 and the surface of the planarization layer 27 away from the array substrate 01 is greater than the distance between the top end of the second definition portion 32 and the surface of the planarization layer 27 away from the array substrate 01. Distances between the top ends of the plurality of third definition portions 33 and the surface of the planarization layer 27 away from the array substrate 01 increase in sequence in the direction from the first definition portion 31 to the second definition portion 32. The distance between the top end of the third definition portion 33 and the surface of the planarization layer 27 away from the array substrate 01 is 0.3-1 μm. The height of the third definition portion 33 can also be slightly adjusted according to its own different materials, and for details, reference may be made to the first definition portion 31 and the second definition portion 32, which will not be described in detail here.

In such embodiment, the first definition portion 31, the second definition portion 32 and the third definition portion 33 have different heights from the planarization layer 27, which helps to adjust the flow velocity of the ink and solve the problem of ink gathering at one end.

Likewise, in an embodiment shown in FIG. 2, the liquid repellency of the first definition portion 31 in such embodiment is less than the liquid repellency of the second definition portion 32. When the first definition layer 3 further includes the plurality of third definition portions 33, the liquid repellency of the plurality of third definition portions 33 increases sequentially in the direction from the first definition portion 31 to the second definition portion 32. In the embodiment, as the liquid repellency increases, the flow velocity of the ink gradually slows down, which helps to improve the problem of ink gathering at one end. In the present disclosure, a magnitude of the liquid repellency of each definition portion can be roughly judged by a contact angle. The larger the contact angle, the stronger the liquid repellency. Contact angles of the first definition portion and the second definition portion are approximately 0-40°.

The ends of the first definition portion 31 and the second definition portion 32 close to the array substrate 01 have the liquid affinity, the ends of the first definition portion 31 and the second definition portion 32 away from the array substrate 01 have the liquid repellency, and the liquid repellency of the end of the first definition portion 31 away from the array substrate 01 is less than the liquid repellency of the end of the second definition portion 32 away from the array substrate 01.

The materials of the first definition portion 31 and the second definition portion 32 may be doped liquid-repellent materials, and when the doped liquid-repellent material is baked, a liquid repellent component in this material will move to the surface, such as moving away from the array substrate 01. Thus, each definition portion with a liquid affinitive bottom end and a liquid repellent top end is formed. The doped material may include a fluorine-containing polymer, such as a copolymer of methyl methacrylate (MMA) and dodecafluoroheptyl methacrylate (also known as poly (methyl methacrylate-dodecafluoroheptyl methacrylate)), and may also include liquid affinitive magnetic nanoparticles, etc.

As shown in FIGS. 10 and 11, in some other embodiments, the first definition portion 31 includes a first bottom definition layer 311 and a first top definition layer 312. The first bottom definition layer 311 is disposed on a side of the array substrate 01. The first top definition layer 312 is disposed on a side of the first bottom definition layer 311 away from the array substrate 01, and the first top definition layer 312 includes at least two first definition dams 3121 extending along the first direction X, and the at least two first definition dams 3121 are arranged at intervals along the second direction Y. The number of first definition dams 3121 may be two, three, four or more.

The second definition portion 32 includes a second bottom definition layer 321 and a second top definition layer 322. The second bottom definition layer 321 is disposed on a side of the array substrate 01. The second top definition layer 322 is disposed on a side of the second bottom definition layer 321 away from the array substrate 01, and the second top definition layer 322 includes at least two second definition dams 3221 extending along the first direction X, and the at least two second definition dams 3221 are arranged at intervals along the second direction Y. The number of first definition dams 3121 may be two, three, four or more.

Each first definition dam 3121 has a bottom end close to the first bottom definition layer 311 and a top end away from the first bottom definition layer 311, and each second definition dam 3221 has a bottom end close to the second bottom definition layer 321 and a top end away from the second bottom definition layer 321. The maximum value of a distance between the bottom end and the top end of the first definition dam 3121 is smaller than the maximum value of a distance between the bottom end and the top end of the second definition dam 3221.

In the present disclosure, the distance between the bottom end and the top end of the definition dam is a height of the definition dam. The height of the first definition dam 3121 is less than the height of the second definition dam 3221 and less than the height of the third definition dam 3321. The heights of individual first definition dams 3121 may be the same or different. Similarly, the heights of individual second definition dams 3221 may be the same or different, and the heights of individual third definition dams 3321 in a single third definition portion 33 may be the same or different, as shown in FIG. 15 to FIG. 17. The maximum value of the distance between the bottom end and the top end of the first definition dam 3121 refers to a height value of a first definition dam 3121 with the highest height among the plurality of first definition dams 3121. Similarly, the maximum value of the distance between the bottom end and the top end of the second definition dam 3221 refers to a height value of a second definition dam 3221 with the highest height among the plurality of second definition dams 3221. The maximum value of the distance between the bottom end and the top end of the third definition dam 3321 refers to a height value of a third definition dam 3321 with the highest height among the plurality of third definition dams 3321. The highest height values of the third definition dams 3321 of the plurality of third definition portions 33 increase in sequence in the direction from the first definition portion 31 to the second definition portion 32.

In the embodiment, thicknesses of the first bottom definition layer 311 and the second bottom definition layer 321 are both 0.2-0.3 μm, as long as they can cover the first electrode layer 51. The materials of the first definition portion 31 and the second definition portion 32 include liquid-affinitive materials, and the distances between the bottom ends and the top ends of the first definition dam 3121 and the second definition dam 3221 are 0.3-0.7 μm. The materials of the first definition portion 31 and the second definition portion 32 include liquid-repellent materials, and the distances between the bottom ends and the top ends of the first definition dam 3121 and the second definition dam 3221 are 0.3-0.5 μm. When the liquid-repellent material is used, the height of each definition dam is relatively low to avoid the ink in each sub-pixel area 30 from being unable to circulate due to the excessive height.

As shown in FIG. 18, in some embodiments of the present disclosure, the first definition layer 3 further includes a plurality of fifth definition portions 34, which extend along the first direction X and are arranged at intervals along the second direction Y. An area defined between two adjacent fifth definition portions 34 is a communication area 02. Each communication area 02 includes at least one first definition portion 31, at least one second definition portion 32, and may further include at least one third definition portion 33. The fifth definition portion 34 has a bottom end close to the array substrate 01 and a top end away from the array substrate 01, and a distance between the bottom end and the top end of the fifth definition portion 34 is greater than the distance between the bottom end and the top end of other definition portions in the first definition layer 3. Specifically, the distance between the bottom end and the top end of the fifth definition portion 34 is greater than 1.2 μm. A material of the fifth definition portion 34 may include a liquid-repellent material. The hole injection layers 52 of the sub-pixel areas 30 in the same column in each communication area 02 are in communication, and the hole injection layers 52 of the sub-pixel areas 30 of two adjacent communication areas 02 are not in communication.

Embodiments of the present disclosure further provide a method for manufacturing a display panel, including:
in step S100, an array substrate 01 is provided; and
in step S200, a first definition layer 3 is formed on a side of the array substrate 01. The first definition layer 3 includes a first definition portion 31 and a second definition portion 32. The first definition portion 31 and the second definition portion 32 both extend along a first direction X, and the second definition portion 32 is located on a side of the first definition portion 31 along a second direction Y. The first definition portion 31 and the second definition portion 32 both have a bottom end close to the array substrate 01 and a top end away from the array substrate 01, and a distance between the bottom end and the top end of the first definition portion 31 is smaller than a distance between the bottom end and the top end of the second definition portion 32.

In some embodiments of the present disclosure, the method for manufacturing the display panel further includes steps S300 and S400.

In the step S300, a second definition layer 4 is formed on a side of the first definition layer 3 away from the array substrate 01, the second definition layer 4 includes a plurality of fourth definition portions 41 extending along the second direction Y and arranged at intervals along the first direction X, and a plurality of sub-pixel areas 30 are defined by the first definition layer 3 and the second definition layer 4. In this step, the material of the second definition layer 4 may include a liquid-repellent material. Specifically, a liquid-repellent material layer may be formed on a side of the first definition layer 3 away from the array substrate, and then the liquid-repellent material layer is exposed and developed to form the second definition layer 4. A thickness of the liquid-repellent material layer may be 1-1.5 μm, and a thickness of the formed second definition layer 4 is not less than 1.2 μm, that is, a distance between the top end and the bottom end of the fourth definition portion 41 is not less than 1.2 μm.

In the step S400, a hole injection material solution is added into a sub-pixel, and hole injection layers 52 corresponding to sub-pixel areas 30 located on both sides of the first definition portion 31 along the second direction Y or hole injection layers 52 corresponding to sub-pixel areas 30 located on both sides of the second definition portion 32 are in communication.

Furthermore, the hole injection material solution in each sub-pixel area 30 has a first flow velocity, a velocity direction of the first flow velocity is a first direction, and the first direction is parallel to the second direction Y.

On the same horizontal plane, a first flow velocity in a sub-pixel area 30 located on a side of the first definition portion 31 away from the second definition portion 32, a first flow velocity in a sub-pixel area 30 located between the first definition portion 31 and the second definition portion 32, and a first flow velocity in a sub-pixel area 30 located on a side of the second definition portion 32 away from the first definition portion 31 decrease successively in magnitude. In this way, it is helpful to prevent the hole injection material solution in the plurality of sub-pixel areas 30 from gathering toward one end due to the tilt of the printer table, thereby improving the uniformity of film formation of each sub-pixel area 30.

In some embodiments of the present disclosure, between the step S100 and the step S200, the method for manufacturing the display panel further includes:
in step S110, a planarization layer 27 is formed on a side of the array substrate 01.

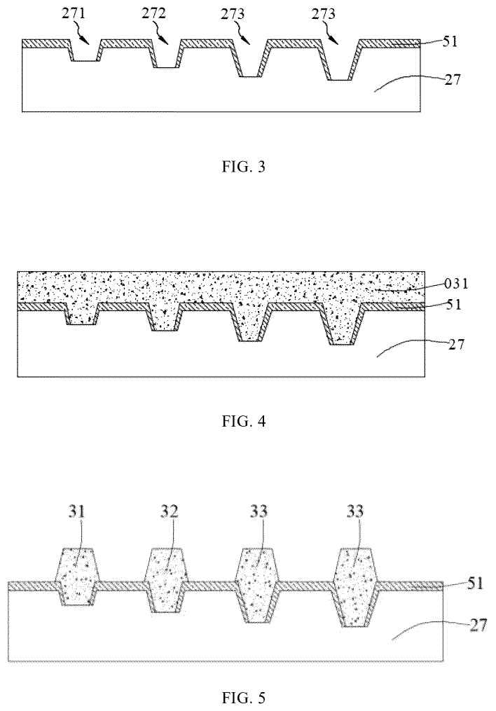

As shown in FIGS. 2 to 5, in the embodiment shown in FIG. 2, the step S200 includes:
in step S210, as shown in FIG. 3, a first groove 271 and a second groove 272 are formed in the planarization layer 27, and a depth of the second groove 272 is greater than a depth of the first groove 271;
in step S220, with continued reference to FIG. 3, a first electrode layer 51 is formed on a side of the planarization layer 27 away from the array substrate 01, the first electrode layer 51 includes a plurality of first electrodes, and the first electrode layer 51 exposes the first groove 271 and the second groove 272;
in step S230, as shown in FIG. 4, a first liquid-repellent material layer 031 is formed on a side of the first electrode layer 51 away from the array substrate 01, and the first liquid-repellent material layer 031 fills the first groove 271 and the second groove 272; and
in step S240, as shown in FIG. 5, the first liquid-repellent material layer 031 is exposed and developed to form the first definition portion 31 and the second definition portion 32, and an orthographic projection of the first groove 271 on the array substrate 01 is located within an orthographic projection of the first definition portion 31 on the array substrate 01, and an orthographic projection of the second groove 272 on the array substrate 01 is located within an orthographic projection of the second definition portion 32 on the array substrate 01.

In the embodiment, forming the first liquid-repellent material layer 031 on the side of the first electrode layer 51 away from the array substrate 01 in the step S210 includes:
in step S211, a first liquid-repellent solution is coated on a side of the first electrode layer 51 away from the array substrate 01, and the first groove 271 and the second groove 272 are filled with the first liquid-repellent solution; and
in step S212, the first liquid-repellent solution is pre-baked, so that a liquid-repellent component in the first liquid-repellent solution moves away from the array substrate 01 to obtain the first liquid-repellent material layer 031;
the liquid-repellent material layer has a bottom portion close to the base substrate 1 and a top portion away from the array substrate 01, and the liquid repellency of the liquid-repellent material layer increases in sequence from the bottom portion to the top portion.

In the embodiment, when the first liquid-repellent material layer 031 is exposed, the first liquid-repellent material layer 031 is patterned, and at least partial thickness of a side of the first liquid-repellent material layer 031 away from the array substrate 01 is removed by exposure. This thickness may be 0.1-0.3 μm, which is not specifically limited in the present disclosure.

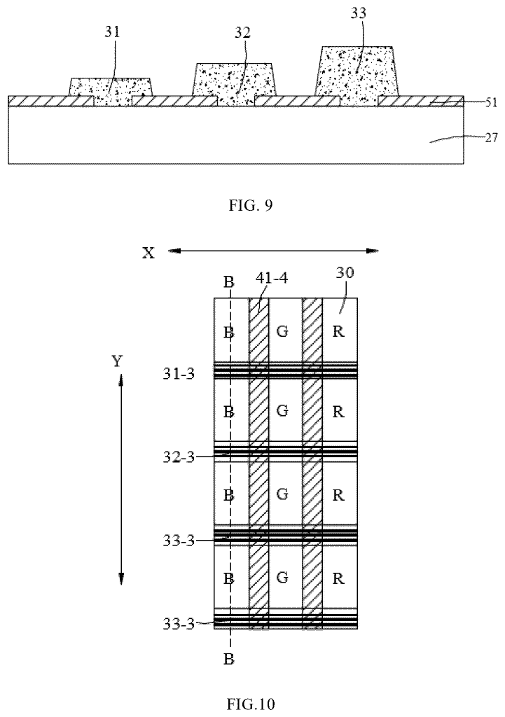

As shown in FIGS. 6 to 9, in the embodiment shown in FIG. 6, the step S200 includes:
in step S210, as shown in FIG. 7, the first electrode layer 51 is formed on the side of the planarization layer 27 away from the array substrate 01, and the first electrode layer 51 includes a plurality of first electrodes;
in step S220, as shown in FIG. 8, a first material layer 032 is formed on a side of the first electrode layer 51 away from the array substrate 01; and
in step S230, as shown in FIG. 9, the first liquid-repellent material layer 031 is exposed to pattern the first material layer 032, and at least partial thickness of a side of the first material layer 032 away from the array substrate 01 is removed by exposure to form the first definition portion 31 and the second definition portion 32;
an exposure amount of the first material layer 032 at a position corresponding to the first definition portion 31 is less than an exposure amount of the first material layer 032 at a position corresponding to the second definition portion 32.

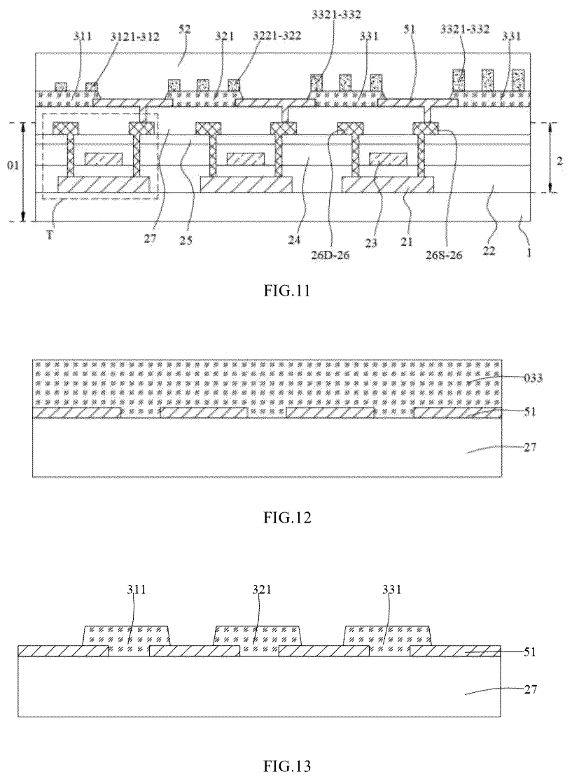

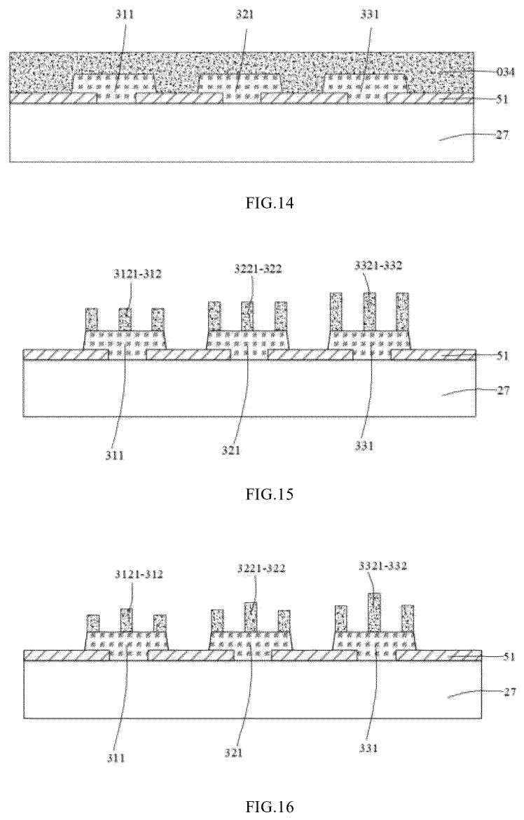

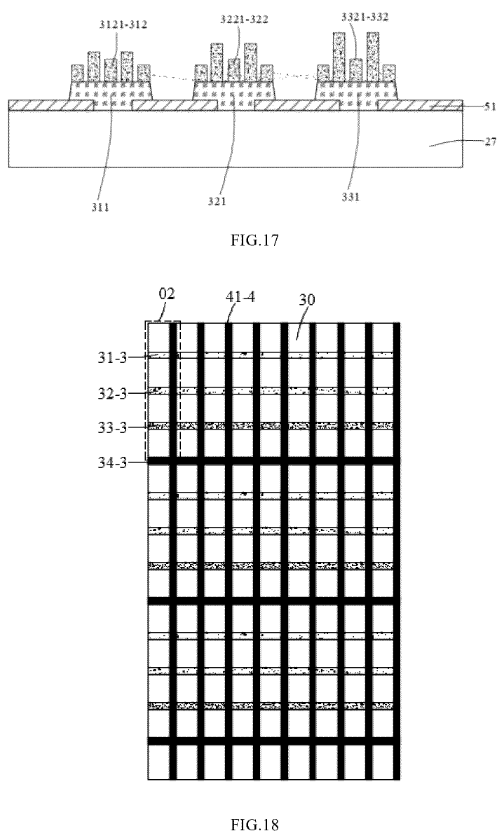

As shown in FIGS. 11 to 16, in the embodiment shown in FIG. 11, the step S200 includes:
in step S210, the first electrode layer 51 is formed on the side of the planarization layer 27 away from the array substrate 01, and the first electrode layer 51 includes the plurality of first electrodes. For this step, reference may be made to FIG. 7;
in step S220, as shown in FIG. 12, a liquid-affinitive material layer 033 is formed on the side of the first electrode layer 51 away from the array substrate 01;
in step S230, as shown in FIG. 13, the liquid-affinitive material layer 033 is exposed and developed to form a first bottom definition layer 311 and a second bottom definition layer 321;
in step S240, as shown in FIG. 14, a buffer material layer 034 is formed on a side of the first bottom definition layer 311 and the second bottom definition layer 321 away from the array substrate 01;
in step S250, as shown in FIG. 15, FIG. 16 or FIG. 17, the buffer material layer 034 is exposed and developed to form a first top definition layer 312 and a second top definition layer 322. The first top definition layer 312 includes at least two first definition dams 3121 extending along the first direction X and arranged at intervals along the second direction Y. The second top definition layer 322 includes at least two second definition dams 3221 extending along the first direction X and arranged at intervals along the second direction Y. In this step, individual definition dams of different heights can be formed by adjusting the exposure amount.

Embodiments of the present disclosure further provide a display device, including a display panel, which may be the display panel of any of the above embodiments. For the specific structure and beneficial effects thereof, reference may be made to the embodiments of the display panel above, which will not be described in detail here. The display device of the present disclosure may be an electronic device such as a mobile phone, a tablet computer, a television, etc., which will not be listed one by one here.

It should be noted that although the various steps of the method of the present disclosure are described in a particular order in the drawings, this is not required or implied that the steps must be performed in the specific order, or all the steps shown must be performed to achieve the desired result. Additionally or alternatively, certain steps may be omitted, multiple steps may be combined into one step, and/or one step may be decomposed into multiple steps and so on, which should be regarded as a part of the present disclosure.

It should be understood that the present disclosure is not limited to the detailed structure and arrangement of the components proposed by the present specification. The present disclosure is capable of having other embodiments, and be carried out and implemented in various manners. The foregoing variations and modifications fall within the scope of the present disclosure. It should be understood that the present disclosure disclosed and defined by the present specification extends to all alternative combinations of two or more of the individual features apparent or recited herein and/or in the drawings. All of these various combinations constitute a number of alternative aspects of the present disclosure. The embodiments described in the present specification are illustrative of the best mode for carrying out the present disclosure and will enable those skilled in the art to utilize the present disclosure.

1. A display panel, comprising:
an array substrate; and
a first definition layer, disposed on a side of the array substrate, and comprising a first definition portion and a second definition portion, wherein the first definition portion and the second definition portion are both extended along a first direction, the second definition portion is located on a side of the first definition portion along a second direction, the first definition portion and the second definition portion are both provided with a bottom end close to the array substrate and a top end away from the array substrate, and a distance between the bottom end and the top end of the first definition portion is smaller than a distance between the bottom end and the top end of the second definition portion.

2. The display panel according to claim 1, wherein liquid repellency of the first definition portion is smaller than liquid repellency of the second definition portion.

3. The display panel according to claim 2, wherein ends of the first definition portion and the second definition portion close to the array substrate have liquid affinity;
ends of the first definition portion and the second definition portion away from the array substrate have the liquid repellency; and
the liquid repellency of the end of the first definition portion away from the array substrate is smaller than the liquid repellency of the end of the second definition portion away from the array substrate.

4. The display panel according to claim 1, wherein the first definition layer further comprises:
a plurality of third definition portions, extended along the first direction, wherein the plurality of third definition portions are arranged at intervals along the second direction on a side of the second definition portion away from the first definition portion;
a third definition portion is provided with a bottom end close to the array substrate and a top end away from the array substrate, and a distance between the bottom end and the top end of the third definition portion is greater than the distance between the bottom end and the top end of the second definition portion; and
distances between bottom ends and top ends of the plurality of third definition portions increase sequentially in a direction from the first definition portion to the second definition portion.

5. The display panel according to claim 1, wherein the display panel further comprises:
a planarization layer, disposed between the array substrate and the first definition layer, wherein the planarization layer is provided with a first groove and a second groove, and a depth of the second groove is greater than a depth of the first groove;
wherein an orthographic projection of the first groove on the array substrate is located within an orthographic projection of the first definition portion on the array substrate, and an orthographic projection of the second groove on the array substrate is located within an orthographic projection of the second definition portion on the array substrate; and
at least part of the first definition portion is filled in the first groove, and at least part of the second definition portion is filled in the second groove.

6. The display panel according to claim 5, wherein the first definition layer further comprises a plurality of third definition portions;
the planarization layer is further provided with a plurality of third grooves, a depth of a third groove is greater than the depth of the second groove, and the third grooves are arranged in a one-to-one correspondence with the third definition portions in a direction perpendicular to the array substrate;
an orthographic projection of a third groove on the array substrate is located within an orthographic projection of a third definition portion on the array substrate, and at least part of the third definition portion is filled in the third groove; and
depths of the plurality of third grooves increase sequentially in a direction from the first groove to the second groove.

7. The display panel according to claim 6, wherein depths of the first groove, the second groove and the third grooves are 0.2-0.7 μm; and
wherein the distance between the bottom end and the top end of the first definition portion, the distance between the bottom end and the top end of the second definition portion, and distances between bottom ends and top ends of the third definition portions are all 0.3-0.8 μm.

8. (canceled)

9. The display panel according to claim 1, wherein the display panel further comprises:
a planarization layer, disposed between the array substrate and the first definition layer; and
a distance between the top end of the first definition portion and a surface of the planarization layer away from the array substrate is smaller than a distance between the top end of the second definition portion and the surface of the planarization layer away from the array substrate.

10. The display panel according to claim 9, wherein the first definition layer further comprises a plurality of third definition portions, and a distance between a top end of a third definition portion and the surface of the planarization layer away from the array substrate is greater than the distance between the top end of the second definition portion and the surface of the planarization layer away from the array substrate; and
distances between top ends of the plurality of third definition portions and the surface of the planarization layer away from the array substrate increase sequentially in a direction from the first definition portion to the second definition portion.

11. The display panel according to claim 9, wherein materials of the first definition portion and the second definition portion comprise liquid-affinitive materials, and the distance between the top end of the first definition portion and the surface of the planarization layer away from the array substrate and the distance between the top end of the second definition portion and the surface of the planarization layer away from the array substrate are 0.3-1 μm.

12. The display panel according to claim 9, wherein materials of the first definition portion and the second definition portion comprise liquid-repellent materials, and the distance between the top end of the first definition portion and the surface of the planarization layer away from the array substrate and the distance between the top end of the second definition portion and the surface of the planarization layer away from the array substrate are 0.3-0.5 μm.

13. The display panel according to claim 1, wherein the first definition portion comprises:
a first bottom definition layer, disposed on the side of the array substrate; and
a first top definition layer, disposed on a side of the first bottom definition layer away from the array substrate, wherein the first top definition layer comprises at least two first definition dams extended along the first direction, and the at least two first definition dams are arranged at intervals along the second direction;
the second definition portion comprises:
a second bottom definition layer, disposed on the side of the array substrate; and
a second top definition layer, disposed on a side of the second bottom definition layer away from the array substrate, wherein the second top definition layer comprises at least two second definition dams extended along the first direction, and the at least two second definition dams are arranged at intervals along the second direction;
wherein each of the first definition dams has a bottom end close to the first bottom definition layer and a top end away from the first bottom definition layer, and each of the second definition dams has a bottom end close to the second bottom definition layer and a top end away from the second bottom definition layer; and
a maximum value of a distance between the bottom end and the top end of the first definition dam is smaller than a maximum value of a distance between the bottom end and the top end of the second definition dam.

14. The display panel according to claim 13, wherein the display panel further comprises a plurality of third definition portions;
a third definition portion comprises:
a third bottom definition layer, disposed on the side of the array substrate; and
a third top definition layer, disposed on a side of the third bottom definition layer away from the array substrate, wherein the third top definition layer comprises at least two third definition dams extended along the first direction, and the at least two third definition dams are arranged at intervals along the second direction;
wherein each of the third definition dams has a bottom end close to the third bottom definition layer and a top end away from the third bottom definition layer; and
a maximum value of a distance between the bottom end and the top end of the third definition dam is greater than the maximum value of the distance between the bottom end and the top end of the second definition dam.

15. The display panel according to claim 13, wherein thicknesses of the first bottom definition layer and the second bottom definition layer are both 0.2-0.3 μm.

16. The display panel according to claim 13, wherein materials of the first definition portion and the second definition portion comprise liquid-affinitive materials, and the distance between the bottom end and the top end of the first definition dam and the distance between the bottom end and the top end of the second definition dam are both 0.3-0.7 μm.

17. The display panel according to claim 13, wherein materials of the first definition portion and the second definition portion comprise liquid-repellent materials, and the distance between the bottom end and the top end of the first definition dam and the distance between the bottom end and the top end of the second definition dam are both 0.3-0.5 μm.

18. The display panel according to claim 1, wherein the display panel further comprises:
a second definition layer, comprising a plurality of fourth definition portions extended along the second direction and arranged at intervals along the first direction, wherein a plurality of sub-pixel areas are defined by the first definition layer and the second definition layer; and
a hole injection layer, located in each of the sub-pixel areas, wherein hole injection layers corresponding to sub-pixel areas located on both sides of the first definition portion along the second direction or hole injection layers corresponding to sub-pixel areas located on both sides of the second definition portion along the second direction are in communication.

19. The display panel according to claim 18, wherein the first definition layer further comprises:
a plurality of fifth definition portions, extended along the first direction and arranged at intervals along the second direction;
the first direction is a row direction, and the second direction is a column direction;
an area defined between two adjacent fifth definition portions is a communication area, and the communication area comprises at least one first definition portion and at least one second definition portion; and
hole injection layers of a plurality of sub-pixel areas of the same column in each communication area are in communication, and hole injection layers of sub-pixel areas in two adjacent communication areas are not in communication.

20. A method for manufacturing a display panel, comprising:
providing an array substrate; and
forming a first definition layer on a side of the array substrate, wherein the first definition layer comprises a first definition portion and a second definition portion, the first definition portion and the second definition portion are both extended along a first direction, the second definition portion is located on a side of the first definition portion along a second direction, the first definition portion and the second definition portion are both provided with a bottom end close to the array substrate and a top end away from the array substrate, and a distance between the bottom end and the top end of the first definition portion is smaller than a distance between the bottom end and the top end of the second definition portion.

21. The method for manufacturing the display panel according to claim 20, further comprising:
forming a second definition layer on a side of the first definition layer away from the array substrate, wherein the second definition layer comprises a plurality of fourth definition portions extended along the second direction and arranged at intervals along the first direction, and a plurality of sub-pixel areas are defined by the first definition layer and the second definition layer; and
adding a hole injection material solution into a sub-pixel, wherein hole injection layers corresponding to sub-pixel areas located on both sides of the first definition portion along the second direction or hole injection layers corresponding to sub-pixel areas located on both sides of the second definition portion along the second direction are in communication.
